(19) United States
(12) Patent Application Publication
(10) Pub. No.: US 2020/0196464 A1
(43) Pub. Date: Jun. 18, 2020

(54) MODULAR PROTECTIVE HOUSING FOR A CONTROL UNIT

(71) Applicant: Endress+Hauser Conducta GmbH+Co. KG, Gerlingen (DE)

(72) Inventors: Roman Griesser, Gerlingen (DE); Michael Dieterich, Waiblingen (DE)

(21) Appl. No.: 16/716,692

(22) Filed: Dec. 17, 2019

(30) Foreign Application Priority Data
Dec. 17, 2018 (DE) 10 2018 132 511.8

(51) Int. Cl. H05K 5/02; F16B 5/06; F16B 5/02

(52) U.S. Cl. CPC H05K 5/0217; H05K 5/0017; F16B 5/02; F16B 5/0614

(57) ABSTRACT

The present disclosure relates to a protective module for a modular protective housing. The protective module includes a base plate having a peripheral edge defined by a first edge region, a second edge region, a third edge region opposite the first, and a fourth edge region opposite the second, wherein a first connecting element is arranged on the first edge region, wherein a second connecting element is arranged on the second edge region; wherein a third connecting element is arranged on the third edge region and configured such that the third connecting element is connectable to the first connecting element of another protective module, and wherein a fourth connecting element is arranged on the fourth edge region and configured such that the fourth connecting element is connectable to the second interconnecting element of a further protective module.

### CROSS-REFERENCE TO RELATED APPLICATION

The present application is related to and claims the priority benefit of German Patent Application No. 10 2018 132 511.8, filed on Dec. 17, 2018, the entire contents of which are incorporated herein by reference.

### TECHNICAL FIELD

The present disclosure relates to a modular protective housing for a control unit, for example for an automation field device.

### BACKGROUND

In automation, especially in process automation, control units serving to control sensors are frequently used, for example. Sensors make it possible to detect various process variables such as fill level, flow rate, pressure, temperature, pH value, or conductivity. Actuators, such as valves or pumps, via which the flow rate of a fluid in a pipeline section or the fill level in a container can be changed are used to influence process variables. One type of control units are what are known as field devices, which in principle refer to all devices which are used close to the process and which supply or process process-related information. In the context of the present disclosure, control units also refer to remote I/Os, radio adapters, or general devices that are arranged at the field level, for example. A plurality of such control units which have different dimensions is manufactured and distributed by the patent applicant.

Control units are conventionally protected by a protective housing against environmental influences, for example against UV radiation, contamination, and weather influences.

However, known protective housings or protective covers have the disadvantage that they are designed for a specific control unit with specific dimensions. For a manufacturer offering a plurality of protective housings in its portfolio, these individually designed protective housings create high costs for the design, production, storage, packaging, and transport of these different protective housings.

In order to reduce the costs of designing, manufacturing, and storing individual protective housings, a protective housing which has designed for a control unit with large dimensions may, of course, also be used for a control unit with comparatively small dimensions. However, this is linked with a high space requirement at the predetermined point of use of the protective housing at the user, during storage, and during transport from the manufacturer to the user.

### SUMMARY

It is therefore an object of the present disclosure to provide a protective housing for a plurality of control units with respective different dimensions, which protective housing at the same time minimizes the space requirement of the protective housing during storage and transport.

This object is achieved by the protective module according to the present disclosure for a modular protective housing according to claim 1.

The protective module according to the present disclosure comprises a base plate having a peripheral edge which is formed by a first edge region, a second edge region, a third edge region opposite the first edge region, and a fourth edge region opposite the second edge region, wherein a first connecting element is arranged on the first edge region; wherein a second connecting element is arranged on the second edge region; wherein a third connecting element is arranged on the third edge region and is formed in such a way that the third connecting element is suitable for being connected to the first connecting element of a protective module that is identical to the protective module; wherein a fourth connecting element is arranged on the fourth edge region and is formed such that the fourth connecting element is suitable for being connected to the second connecting element of a protective module identical to the protective module.

The protective module according to the present disclosure makes it possible to provide a modular protective housing using a plurality of protective modules. In this way, depending on the dimension of the one field device to be protected, or of the plurality of field devices to be protected, a suitable protective housing can be created from a plurality of protective modules. The protective module thus enables an individualized and flexible adaptation of the protective housing.

According to one embodiment of the present disclosure, the base plate is square.

According to one embodiment of the present disclosure, each of the connecting elements is formed as an eye and is suitable for receiving a connecting pin.

According to one embodiment of the present disclosure, the first connecting element and the second connecting element are respectively designed as snap bolts, wherein the third connecting element and the fourth connecting element are respectively designed as eyes in order to receive a snap bolt.

According to one embodiment of the present disclosure, the first edge region has a first identification feature and the second edge region has a second identification feature different from the first identification feature, wherein the first identification feature and the second identification feature are two different color labels, for example.

According to one embodiment of the present disclosure, the base plate has at least one retaining device which, for example, is designed in such a way that a breakthrough surface is visible which is suitable for being broken out from the base plate.

The aforementioned object is likewise achieved by the protective housing according to the present disclosure as claimed in claim 7.

The protective housing according to the present disclosure comprises at least two protective modules, wherein the first connecting element of the first protective module is connected to the third connecting element of the second protective module.

According to one embodiment of the present disclosure, at least one protective module is made of a transparent material.

According to one embodiment of the present disclosure, the protective housing further furthermore comprises at least one terminating element which is suitable for being connected to at least one connecting element of the first protective module and/or to at least one connecting element of a further protective module.

According to one embodiment of the present disclosure, the terminating element comprises a first part which is suitable for being connected to a connecting element of the first protective module and has a second part which is suitable for being connected to a connecting element of a further protective module, wherein the first part and the second part are connected to one another so as to be movable.

### BRIEF DESCRIPTION OF THE DRAWINGS

The present disclosure is explained in more detail on the basis of the following figure descriptions:

FIG. 1 shows a view of a protective module according to the present disclosure;

FIG. 2 shows an embodiment of a protective housing with field devices;

FIG. 3 shows a plurality of protective modules for a first embodiment of a protective housing;

FIG. 4 shows an alternative embodiment of a protective housing;

FIG. 5 shows an alternative square embodiment of a protective module;

FIG. 6 shows a plurality of protective modules according to FIG. 5 for a further embodiment of a protective housing;

FIG. 7 shows an embodiment of connecting elements;

FIG. 8 shows an alternative embodiment of connecting elements, and

FIG. 9 shows an embodiment of a protective housing having various terminating elements.

### DETAILED DESCRIPTION

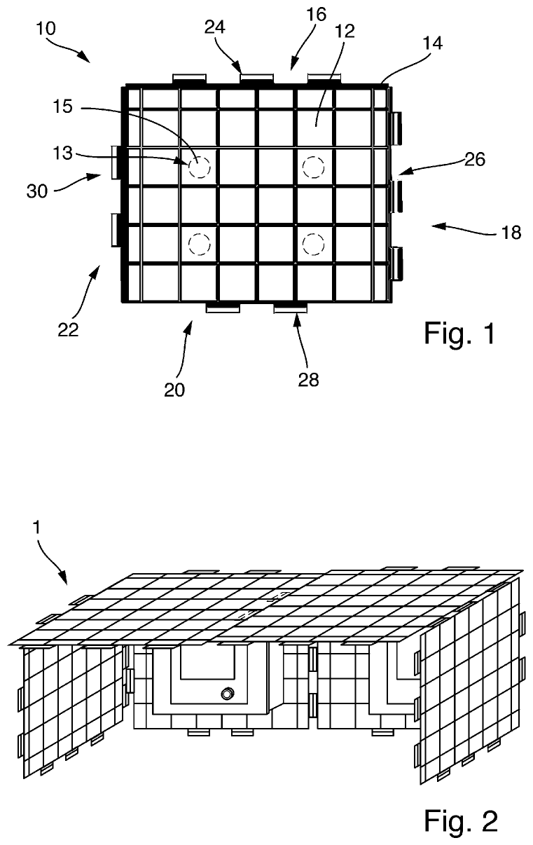

FIG. 1 shows a protective module 10 for a modular protective housing 1 which is suitable for accommodating a field device protected from environmental influences.

“Modular” is understood in the following to mean an extensibility or modifiability of the protective housing 1. This means that a protective housing 1 can be supplemented by further protective modules 10 in such a way that a plurality of field devices or a larger field device can be located under the protective housing 1. This is especially advantageous if a first field device is to be retrofitted with a further field device mounted next to the first field device, or an existing field device is to be replaced by a larger field device. A reduction in the size of the protective housing is also possible, of course. Such a protective housing offers a user an optimal adaptability to future requirements and, at the same time, a minimal effort to implement such an adaptation to future requirements and at the same time to realize this adaptation with minimal costs.

As shown in FIG. 1, the protective module 10 includes a base plate 12 having a peripheral edge 14. The base plate has a rectangular shape. In alternative embodiments, the protective module 100 has a square shape. The edge 14 is formed by a first edge region 16, a second edge region 18, a third edge region 20 opposite the first edge region 16, and a fourth edge region 22 opposite the second edge region 18.

A first connecting element 24 is arranged on the first edge region 16. A second connecting element 26 is arranged on the second edge region 18. A third connecting element 28 is arranged on the third edge region 20 and is designed such that the third connecting element 28 is suitable for being connected to the first connecting element 24 of a protective module 10 identical to the protective module 10. A fourth connecting element 30 is arranged on the fourth edge region 22 and is designed such that the fourth connecting element 30 is suitable for being connected to the second connecting element 26 of a protective module 10 identical to the protective module 10.

The first connecting element 24 and the third connecting element 28 of the protective module 10, as well as the second connecting element 26 and the fourth connecting element 30 of the protective module 10, are of complementary design. This enables a simple extensibility of the protective module 10 via identical further protective modules 10. The protective module 10 can thus be extended on all four sides in order to form protective housings 1 of different sizes. Exemplary embodiments of the connecting elements 24, 26, 28, 30 will be described later.

In order to make the compatibility of different connecting elements more rapidly evident to the user, connecting elements or the corresponding edge regions matching one another can have an identical identification feature; for example, they can be identical in color. Alternatively, identical symbols or labels may also be used to detect the compatibility of the connecting elements.

An extension of the protective module 10 on or toward one side means not only an extension in a single lateral direction, for example a direction in the same plane as the protective module 10; rather, such an extension of the protective module 10 also means further lateral directions which, for example, are not in the same plane as the protective module 10. If reference is made hereinafter to the top, bottom, right, or left, this means not only an extension of the protective module 10 in the same plane as the protective module 10 but also further planes.

As shown in FIG. 1, the base plate 12 of the protective module 10 can also have a retaining device 13. The retaining device 13 is visible as a breakthrough surface 15, for example. The breakthrough surface 15 is designed such that it can be broken out from the base plate 12 by hand. Alternatively, the breakthrough surface can be broken out with a tool, for example a screwdriver. Alternatively, the retaining device 13 can be designed, for example, as an opening or as a plurality of holes in order to form a through-hole for a screw. The opening may have any shape. The embodiments described further below can, of course, also have such a retaining device 13.

FIG. 2 shows an embodiment of a protective housing 1 having two field devices protected by the protective housing 1.

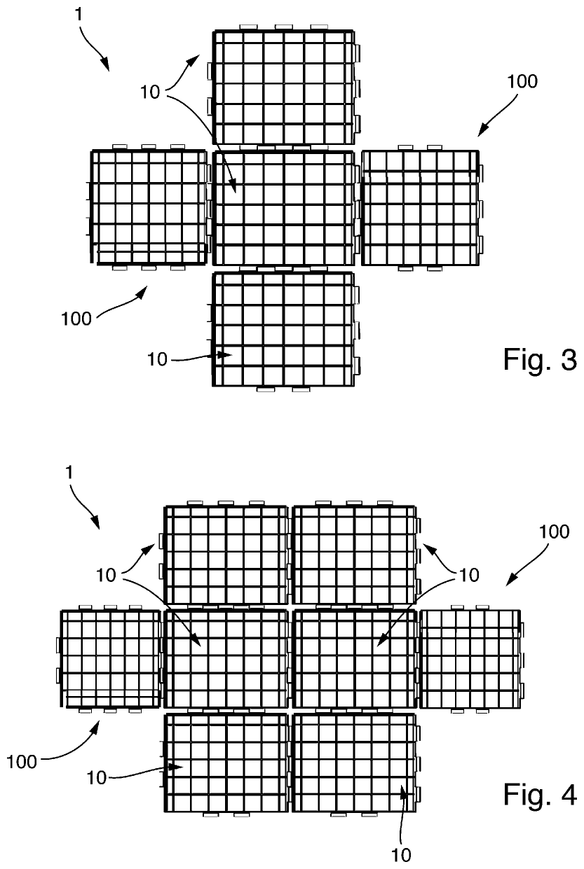

FIGS. 3 and 4 show two embodiments of a protective housing 1. The individual protective modules are partially connected to one another so that the protective housing can be depicted in one plane. The shown protective housings consist of three rectangular protective modules 10, or six rectangular protective modules 10 and two square protective modules 100. The connecting elements are configured to connect the protective modules in such a way that a cuboid protective housing 1 can be formed.

The square protective module 100 differs from the rectangular protective module 10 shown in FIG. 1 only in that all edge regions 16, 18, 20, and 22 have the same length. The length of all edge regions is preferably identical to a length of an edge region of the rectangular protective module 10. As can be seen from FIGS. 3 and 4, the square protective module 100 is therefore suitable for extending a rectangular protective module 10, for example to the right and left, so that a cuboid protective housing 1 can be formed.

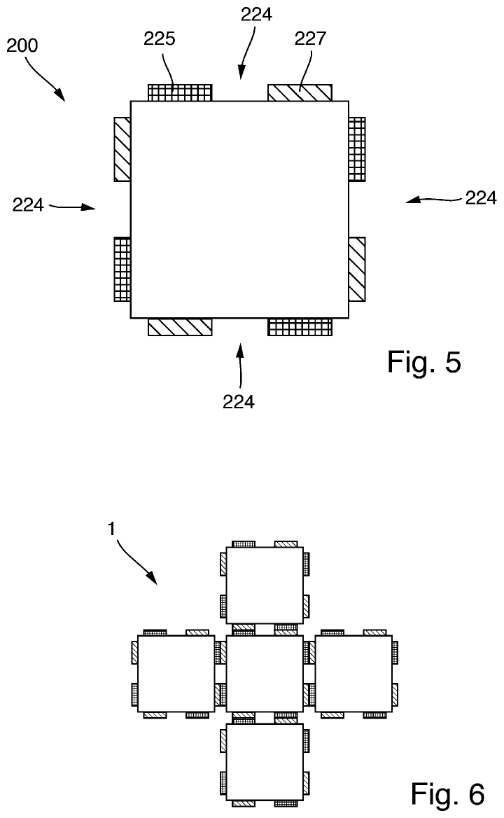

FIG. 5 shows an alternative embodiment of a square protective module 200. The square protective module 200 differs from the square protective module 100 in that all the connecting elements 224 which are arranged on each edge region are identical. The square protective module 200 can thus be connected to an identical square protective module 200 via each edge region or via each connecting element 224. The connection of the protective modules thus becomes simple and convenient for the user. The square protective modules make it possible to create a cubic protective housing, for example. Of course, cuboidal protective housings are also possible if, for example, the protective housing is extended laterally via further protective modules.

Each of the connecting elements 224 has a first connector 225 and a second connector 227 compatible with or complementary to the first connector. The first connector 225 is configured to receive the second connector 227 of a further protective module 200. The second connector 227 is configured to receive the first connector 225 of a further protective module 200. Exemplary embodiments of the connecting element 224, or the first connector 225 and the second connector 227, will be described later.

FIG. 6 shows a protective housing 1 consisting exclusively of square protective modules 200. It can be seen from FIG. 6 that an assembly of the protective housing 1 becomes possible very easily, since it is not necessary to consider the location at which the protective modules 200 must be placed in order to create the protective housing 1.

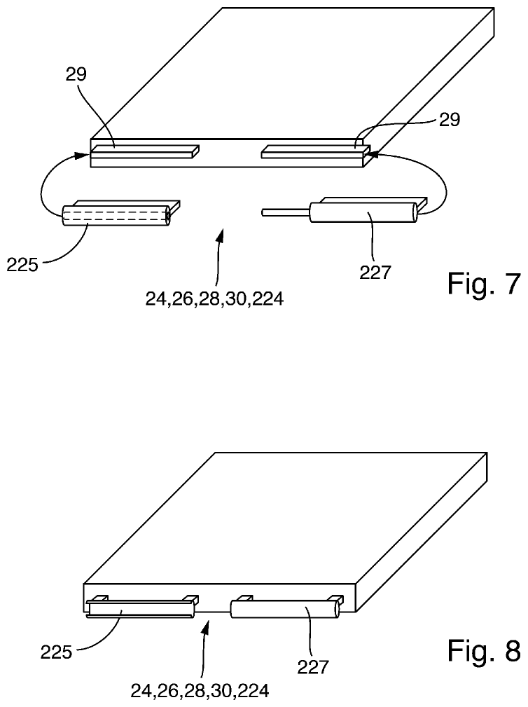

FIGS. 7 and 8 show exemplary embodiments for the connecting elements 24, 26, 28, 30, and 224, or the first connector 225 and second connector 227, respectively.

FIG. 7 shows an embodiment of a connecting element, wherein the first connector 225 is an eye and the second connector 227 is a pin complementary to the eye. An advantage of the embodiment of the connecting element as eye and pin is the ability to rotate the protective module about an axis of the pin. The protective module may, for example, comprise a groove 29 in which the eye and/or the pin may be received. The groove has, for example, a cross section in the form of what is known as a dovetail.

FIG. 8 shows an embodiment of a connecting element, wherein the first connector 225 is a clip. The second connector 227 is designed, for example, as a bolt complementary to the clip. This embodiment of the connecting elements allows a simple plug connection by the user.

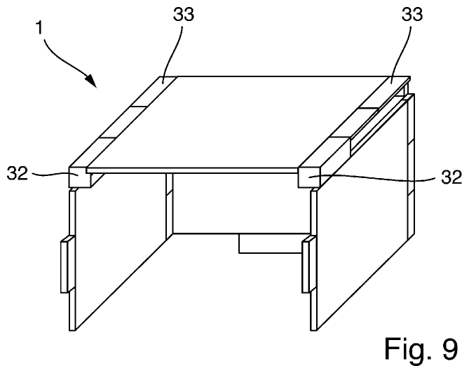

FIG. 9 shows a protective housing having a first terminating element 32 and a second terminating element 33. Both terminating elements are suitable for being connected to the connecting elements of the various protective modules in order to terminate and/or connect the protective modules at their edge. A connection of the protective modules via the terminating elements 32, 33 increases the stability of the protective housing 1.

The first terminating element 32 is configured to be arranged between two protective modules, so that the two protective modules are tightly sealed. “Tightly” denotes rainproof or airtight, for example.

The second terminating element 33 is configured to be arranged between two protective modules, so that the two protective modules are separated by a ventilation gap. If the second terminating element 33 is mounted on the top of the protective housing as shown in FIG. 9, heat can be dissipated from the protective housing in a simple manner. This is especially advantageous if the protective housing is exposed to strong solar radiation during its use.

In one embodiment (not shown), at least one protective module of a protective housing 1 is designed to be transparent. A transparent protective module is especially suitable as a front protection for a protective housing 1. Thus, a field device in the protective housing 1 is easily visible to the user, and at the same time such a protective housing with transparent protective module 600 offers optimal weather protection.

Claimed is:

1. A protective module for a modular protective housing, the module comprising:
a base plate having a peripheral edge defined by a first edge region, a second edge region, a third edge region opposite the first edge region, and a fourth edge region opposite the second edge region;
a first connecting element arranged on the first edge region;
a second connecting element arranged on the second edge region;
a third connecting element arranged on the third edge region and configured such that the third connecting element is connectable to the first connecting element of an other protective module, the other protective module identical to the protective module;
a fourth connecting element arranged on the fourth edge region and configured such that the fourth connecting element is connectable to the second connecting element of a further protective module, the further protective module identical to the protective module.

2. The protective module of claim 1, wherein the base plate is square-shaped.

3. The protective module of claim 1, wherein each of the first, second, third and fourth connecting elements includes a first connector and a second connector complementary to the first connector.

4. The protective module of claim 3, wherein the first connector is configured as an eye and the second connector is configured as a complementary pin, or wherein the first connector is configured as a clip and the second connector is configured as a complementary bolt.

5. The protective module of claim 1, wherein the first edge region has a first identification feature and the second edge region has a second identification feature different than the first identification feature.

6. The protective module of claim 1, wherein the base plate has at least one retaining device configured such that a breakthrough surface is visible that is structured for being broken out selectively from the base plate.

7. A protective housing, comprising at least two protective modules according to claim 1, wherein the first connecting element of a first protective module is connected to the third connecting element of a second protective module.

8. The protective housing of claim 7, wherein at least one of the at least two protective modules is made of a transparent material.

9. The protective housing of claim 7, further comprising at least one terminating element structured for being connected to at least one connecting element of the first protective module and/or to at least one connecting element of an other protective module.
